(19) United States
(12) Patent Application Publication
(10) Pub. No.: US 2011/0236162 A1
(43) Pub. Date: Sep. 29, 2011

(54) PROCESSING-OBJECT-SUPPORTING MECHANISM, SUPPORTING METHOD, AND CONVEYING SYSTEM INCLUDING THE MECHANISM

(75) Inventors: Toru Shikayama, Fukuoka (JP); Tadataka Noguchi, Fukuoka (JP); Akihito Toyota, Fukuoka (JP); Yoshihiro Kusama, Fukuoka (JP)

(73) Assignee: KABUSHIKI KAISHA YASKAWA DENKI, Kitakyushu-shi (JP)

(21) Appl. No.: 13/033,610

(22) Filed: Feb. 24, 2011

(30) Foreign Application Priority Data
Mar. 24, 2010 (JP) 2010-068567

(51) Int. Cl. H01L 21/677

(52) U.S. Cl. 414/222.01

(57) ABSTRACT

A processing-object-supporting mechanism includes at least three devices each including a lift pin, a motor, and a drive controller. The lift pin contacts a processing object to support the processing object. The processing object is transferred between a conveying arm and the processing-object-supporting mechanism. The motor lifts and lowers the lift pin. The drive controller is configured to control the motor. The drive controller of each of the at least three devices is configured to control the motor of each of the at least three devices independently.

### CROSS-REFERENCES TO RELATED APPLICATIONS

The present application claims priority under 35 U.S.C. §119 to Japanese Patent Application No. 2010-068567 filed on Mar. 24, 2010. The contents of this application are incorporated herein by reference in their entirety.

### BACKGROUND OF THE INVENTION

1. Field of the Invention

The present invention relates to a processing-object-supporting mechanism, a supporting method, and a conveying system.

2. Discussion of the Background

An exemplary known processing-object-supporting mechanism, disclosed in Japanese Unexamined Patent Application Publication No. 2008-60402, includes three lift pins that lift and lower a processing object. The three lift pins are simultaneously operated by one lift actuator and one elastic hinge device. Another exemplary known processing-object-supporting mechanism, disclosed in Japanese Unexamined Patent Application Publication No. 2009-16851, includes a plurality of lift pins provided with a plurality of lift actuators, and the lift pins are collectively operated by one lift control device. Some processing-object-supporting mechanisms are used in process chambers and/or conveyance chambers included in processing apparatuses in which various processes such as film formation, etching, oxidation, and dispersion are performed on wafers, which are processing objects. Such process chambers and conveyance chambers are airtight so as to be vacuumed, and are maintained to produce vacuum environments there inside at pressures lower than the atmospheric pressure.

### SUMMARY OF THE INVENTION

According to one aspect of the present invention, a processing-object-supporting mechanism includes at least three devices each including a lift pin, a motor, and a drive controller. The lift pin contacts a processing object to support the processing object. The processing object is transferred between a conveying arm and the processing-object-supporting mechanism. The motor lifts and lowers the lift pin. The drive controller is configured to control the motor. The drive controller of each of the at least three devices is configured to control the motor of each of the at least three devices independently.

According to another aspect of the present invention, a supporting method employed in a supporting mechanism includes transferring a processing object after drive controllers independently control motors respectively such that distances from tips of lift pins to the processing object placed on a conveying arm or to a processing-object-receiving surface of the conveying arm all become equal. The processing object is transferred between the conveying arm and the supporting mechanism. The supporting mechanism includes at least three devices each having one lift pin of the lift pins, one motor of the motors, and one drive controller of the drive controllers. The lift pin contacts the processing object to support the processing object. The motor lifts and lowers the lift pin. The drive controller is configured to control the motor.

According to further aspect of the present invention, a conveying system includes a conveying arm and a supporting mechanism. The conveying arm is configured to convey a processing object. The processing object is transferred from and to the conveying arm with a supporting mechanism. The supporting mechanism includes at least three devices each having a lift pin, a motor, and a drive controller. The lift pin contacts the processing object to support the processing object. The motor lifts and lowers the lift pin. The drive controller is configured to control the motor. The processing object is transferred after the drive controller of each of the at least three devices independently controls the motor of each of the at least three devices such that distance from a tip of the lift pin of each of the at least three devices to the processing object placed on the conveying arm or to a processing-object-receiving surface of the conveying arm all become equal.

According to the other of the present invention, a processing-object-supporting mechanism includes at least three devices each including a lift pin, a motor, and a drive controller. The lift pin contacts a processing object to support the processing object. The processing object is transferred between a conveying arm and the processing-object-supporting mechanism. The motor lifts and lowers the lift pin. The drive controller is configured to control the motor. The motor of each of the at least three devices is arranged to lift and lower the lift pin of each of the at least three devices provided in and fixed to an airtight chamber in which pressure is reduced. The processing object is transferred after the drive controller of each of the at least three devices independently controls the motor of each of the at least three devices in accordance with the pressure inside the airtight chamber such that distance from a tip of the lift pin of each of the at least three devices to the processing object placed on the conveying arm or to a processing-object-receiving surface of the conveying arm all become equal.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 schematically shows a processing-object (wafer)-supporting mechanism according to a first embodiment of the present invention;

FIG. 2 shows the arrangement of lift pins and linear motors according to the first embodiment of the present invention;

FIG. 3 shows the configuration of a linear motor and a position detector according to the first embodiment of the present invention;

FIG. 4 shows the configuration of a linear motor and a position detector according to a second embodiment of the present invention;

FIGS. 5A, 5B, 5C and 5D show a processing-object (wafer)-supporting method according to a third embodiment of the present invention;

FIGS. 6A, 6B, 6C and 6D show a processing-object (wafer)-supporting method according to a fourth embodiment of the present invention;

FIG. 7 shows the arrangement of lift pins and linear motors according to a fifth embodiment of the present invention;

FIGS. 8A and 8B show a processing-object (wafer)-supporting method according to the fifth embodiment of the present invention;

FIG. 9 shows the arrangement of lift pins and linear motors according to a sixth embodiment of the present invention; and

FIG. 10 shows a processing-object (wafer)-supporting method according to the sixth embodiment of the present invention.

### DESCRIPTION OF THE EMBODIMENTS

Embodiments will now be described with reference to the accompanying drawings, wherein like reference numerals designate corresponding or identical elements throughout the various drawings.

### First Embodiment

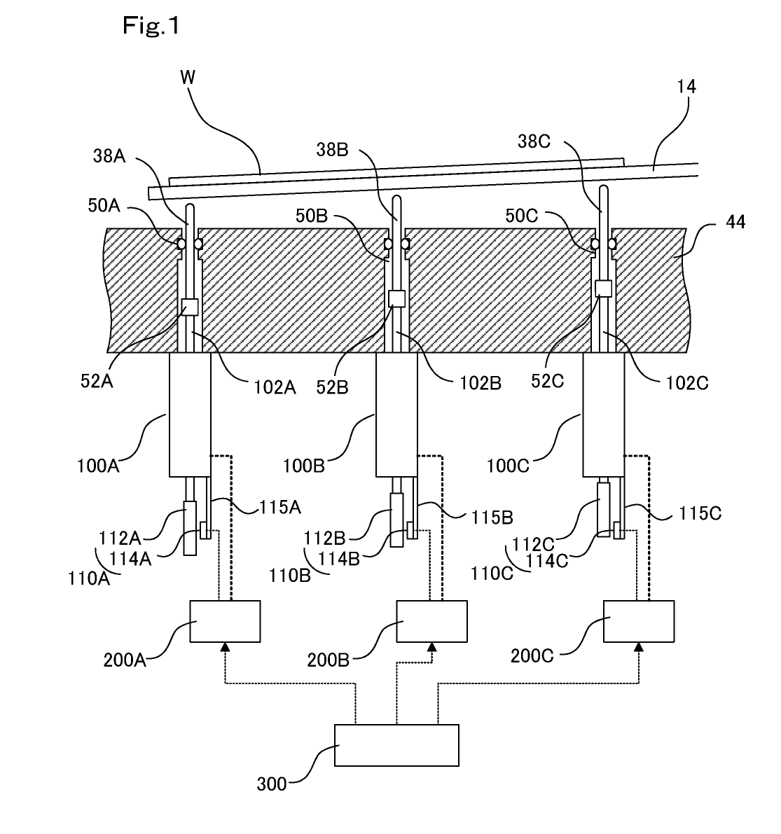

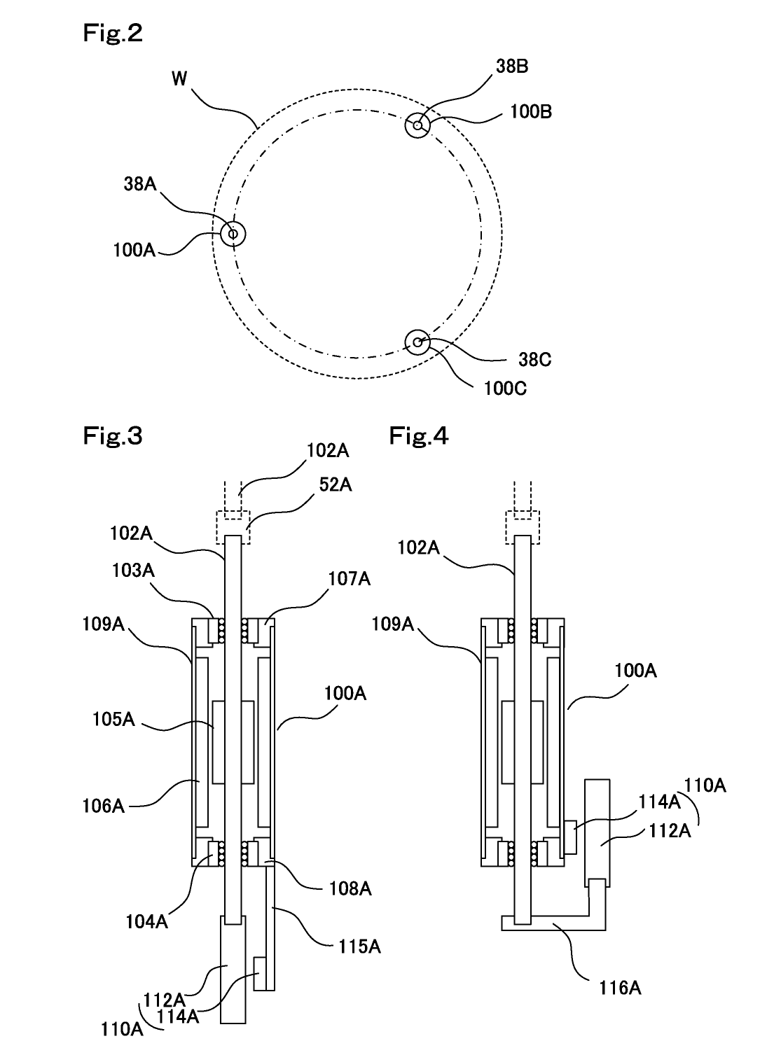

FIG. 1 schematically shows a processing-object-supporting mechanism according to a first embodiment of the present invention (herein, the processing object is a wafer). FIG. 2 is a plan view of the mechanism according to the first embodiment, showing the arrangement of lift pins and linear motors. FIG. 3 shows the configuration of a linear motor and a position detector. Elements shown in FIGS. 1 to 3 include a wafer W as the processing object, a conveying arm 14, a bottom 44 of an airtight chamber, lift pins 38A to 38C, O-rings 50A to 50C, couplings 52A to 52C, linear motors 100A to 100C, movable shafts 102A to 102C, position detectors 110A to 110C, scales 112A to 112C, detector heads 114A to 114C, detector head mounts 115A to 115C, drive control devices 200A to 200C, a position command device 300, linear motion guides 103A and 104A, a field magnet 105A, an armature 106A, brackets 107A and 108A, and a frame 109A.

FIG. 1 schematically shows the processing-object-supporting mechanism in a state where the wafer W, as the processing object, placed on the conveying arm 14 is being transferred in the airtight chamber. In the first embodiment, as shown in FIG. 2, the three lift pins 38A to 38C are arranged along the circumference of a specific circle that is to be concentric with the wafer W. However, in FIG. 1, the lift pins 38A to 38C are schematically shown side by side for easier understanding. The bottom 44 of the airtight chamber has three through-holes, in which the three lift pins 38A to 38C are provided respectively, with the O-rings 50A to 50C fitted around the respective lift pins 38A to 38C so as to maintain the inside of the airtight chamber to be vacuum. The 0-rings 50A to 50C employed in the first embodiment for maintaining the inside of the airtight chamber to be vacuum may be substituted with bellows, as in known techniques. The linear motors 100A to 100C each have a cylindrical shape and are attached to the undersurface of the bottom 44 of the airtight chamber. The movable shafts 102A to 102C extend through and project from the tops and bottoms of the respective linear motors 100A to 100C. The movable shafts 102A to 102C are provided at the upper ends thereof with the lift pins 38A to 38C with the couplings 52A to 52C interposed therebetween, and at the lower ends thereof with the scales 112A to 112C of the position detectors 110A to 110C, respectively. The detector heads 114A to 114C of the position detectors 110A to 110C are attached to the stator sides of the linear motors 100A to 100C with the detector head mounts 115A to 115C interposed therebetween, respectively. Power cables (the bold dotted lines shown in FIG. 1) through which power is supplied to the respective linear motors 100A to 100C and signal cables (the thin dotted lines shown in FIG. 1) through which positional information is input from the respective position detectors 110A to 110C are connected to the drive control devices 200A to 200C provided for the respective linear motors 100A to 100C. In addition, signal cables (the dotted lines with arrow heads shown in FIG. 1) through which position command values are transmitted to the respective drive control devices 200A to 200C are connected to the position command device 300.

FIG. 2 shows the arrangement of the lift pins 38A to 38C and the linear motors 100A to 100C in a state where the processing-object-supporting mechanism is seen from above. The lift pins 38A to 38C and the linear motors 100A to 100C are arranged at constant intervals along the circumference of a circle that is to be concentric with the wafer W. In the first embodiment, the lift pins and associated elements are provided three each, as shown in FIG. 2. It is only necessary to provide N units each including one lift pin; one linear motor configured to lift and lower the lift pin; and one drive control device driving the linear motor individually, where N is an integer of at least 3.

The wafer W is conveyed to the supporting mechanism while being placed on the conveying arm 14. The conveying arm 14 is, for example, a movable part of a horizontal articulated robot. Exemplary horizontal articulated robots are disclosed in Japanese Unexamined Patent Application Publication No. 10-315182 and so forth. The conveying arm 14 corresponds to, for example, the distal part of a movable arm including a plurality of arms connected to one another. The conveying arm 14 is thin and light-weighted. Therefore, the conveying arm 14 has a low flexural rigidity and is often bent from the base to the tip thereof under its own weight. Accordingly, as shown in FIG. 1, the wafer W placed on the conveying arm 14 is tilted with respect to a reference surface (for example, the top surface of the bottom 44) defined in the airtight chamber.

FIG. 3 is a sectional view showing the configurations of the linear motor 100A and the position detector 110A as examples. The linear motors 100B and 100C and the position detectors 110B and 110C have the same configurations as those shown in FIG. 3. The linear motor 100A has a cylindrical shape and includes the movable shaft 102A, the field magnet 105A, the armature 106A, and the frame 109A provided in that order from the inner side. The field magnet 105A is provided around and fixed to the movable shaft 102A. The armature 106A is fixed to the frame 109A. The movable shaft 102A is held by the linear motion guides 103A and 104A on the upper and lower sides, respectively, of the field magnet 105A in such a manner as to be vertically movable. The linear motion guides 103A and 104A are ball splines or the like functioning as rolling guides. The linear motion guides 103A and 104A are fixed to the brackets 107A and 108A, respectively. The brackets 107A and 108A are fixed to the upper and lower ends, respectively, of the frame 109A. The field magnet 105A includes permanent magnets (not shown) arranged such that the north (N) and south (S) magnetic poles appear alternately in the vertical direction. The armature 106A is coiled in such a manner as to generate a traveling magnetic field whose magnetic pole pitch is the same as that of the field magnet 105A. In such a configuration, when a specific current is supplied to the armature 106A in correspondence with the magnetic poles of the field magnet 105A, a thrust acts on the field magnet 105A, whereby the movable shaft 102A is moved vertically.

The movable shaft 102A is provided at the lower end thereof with the scale 112A of the position detector 110A. The detector head mount 115A is attached to the bracket 108A. The detector head 114A of the position detector 110A is attached to the tip of the detector head mount 115A. A specific gap is provided between the scale 112A and the detector head 114A so as to enable position reading. In such a configuration, when the movable shaft 102A is moved vertically, the detector head 114A detects the amount of travel and position of the movable shaft 102A by reading the scale 112A. The position detector 110A may be any of an optical encoder, a magnetic encoder, a resolver, and the like.

In the mechanism configured as described above, the position command device 300 transmits position command values suitable for the amounts of travel and stop positions of the lift pins 38A to 38C to the drive control devices 200A to 200C. In response to this, the drive control devices 200A to 200C control the positions of the respective linear motors 100A to 100C, on the basis of the positions detected by the position detectors 110A to 110C, such that the lift pins 38A to 38C are positioned as indicated by the respective position command values. Thus, the movable shafts 102A to 102C having the lift pins 38A to 38C at the upper ends thereof are moved in accordance with the position command values.

As shown in FIG. 1, the wafer W is tilted with respect to the reference surface because of the bend in the conveying arm 14. Therefore, in the first embodiment, the angles of tilt of the wafer W, placed on the conveying arm 14, or the angles of tilt of a wafer-receiving surface of the conveying arm 14 at positions corresponding to the three lift pins 38A to 38C are measured in advance. The position command values are generated for the respective linear motors 100A to 100C with the angles of tilt taken as correction values. That is, the wafer W is transferred after the N linear motors are independently driven by the respective drive control devices such that the distances from the tips of the N lift pins to the undersurface of the wafer W placed on the conveying arm 14 or to the wafer-receiving surface of the conveying arm 14 all become equal. Hence, even if the wafer W is tilted because of any bend in the conveying arm 14, the positions of the N lift pins are individually controlled to correspond to the tilt of the wafer W. The wafer W is not transferred between the conveying arm 14 and the lift pins before the distances from the tips of the lift pins to the wafer W or to the wafer-receiving surface of the conveying arm 14 all become equal. Therefore, the occurrence of unexpected displacement of the wafer W during the transfer of the wafer W is suppressed. That is, the wafer W is transferred after the virtual plane defined by the tips of the N lift pins and the wafer-receiving surface of the conveying arm 14 become parallel to each other.

Even if the conveying arm 14 is not bent or even if the wafer W to be processed is deformed, for example, warped, after being subjected to high temperature, the wafer W is transferred after the distances from the tips of the lift pins to the wafer W are all made equal so as to correspond to the deformed shape. Therefore, the occurrence of unexpected displacement of the wafer W during the transfer of the wafer W is suppressed, as in the above case.

In the case where the supporting mechanism is used for transferring a processing object in an airtight chamber as in the first embodiment, the force of friction that acts on sealing members, such as the O-rings 50A to 50C, may change depending on the pressure (the degree of vacuum) in the airtight chamber. Particularly, when the airtight chamber is of load-lock type in which a vacuum environment and an atmosphere environment are produced alternately, the force of friction varies between in the vacuum environment and in the atmosphere environment, and the thrust required for moving the linear motors therefore varies. In such a case, the thrust that enables the linear motors to be normally lifted and lowered is measured in advance under each of different degrees of vacuum in the airtight chamber, and the linear motors are controlled in accordance with the degree of vacuum in the airtight chamber when the processing object is actually transferred.

In the supporting mechanism according to the first embodiment employing the linear motors 100A to 100C, no speed reducers or the like producing backlash are provided, and the positions of the lift pins are always detected accurately and are controlled constantly. Therefore, even if the load changes, specifically, even if the forces of friction acting on the O-rings 50A to 50C as the sealing members and the linear motion guides 103 and 104 change, changes in the behavior of the supporting mechanism are suppressed. That is, with the linear motors 100A to 100C, the displacement of the processing object that tends to occur in the known techniques when the processing object is transferred from and to the conveying arm is greatly reduced.

Furthermore, according to the configuration of the linear motors 100A to 100C described in the first embodiment, the lift pin, the linear motor, and the position detector included in each unit are arranged coaxially. Thus, the units of the supporting mechanism each having a long and narrow body are arranged dispersively. Consequently, large spaces are provided among the units of the supporting mechanism. Since such large spaces are allowed for the drive control devices and other electric components, the overall size of the processing apparatus can be reduced.

### Second Embodiment

FIG. 4 shows the configuration of a linear motor and a position detector according to a second embodiment of the present invention. Elements identical with those in the first embodiment are denoted as in the first embodiment, and descriptions thereof are omitted.

Elements shown in FIG. 4 includes an L-shaped scale mount 116A. In the second embodiment, the scale mount 116A has one end thereof attached to the movable shaft 102A, and the other end thereof provided with the scale 112A. The detector head 114A is provided on the frame 109A. A specific gap is provided between the detector head 114A and the scale 112A. That is, the scale mount 116A is formed such that the position detector 110A is positioned on the outer periphery of the frame 109A. Thus, in the second embodiment, the position detector 110A is provided parallel to the linear motor 100A, in contrast to the arrangement according to the first embodiment where the position detector 110A is provided coaxially with the linear motor 100A. With such a configuration, the units of the supporting mechanism each having a reduced height are arranged dispersively. Thus, large spaces are provided among the units of the supporting mechanism while the heights of the units are suppressed. Therefore, the overall size of the processing apparatus can be reduced.

### Third Embodiment

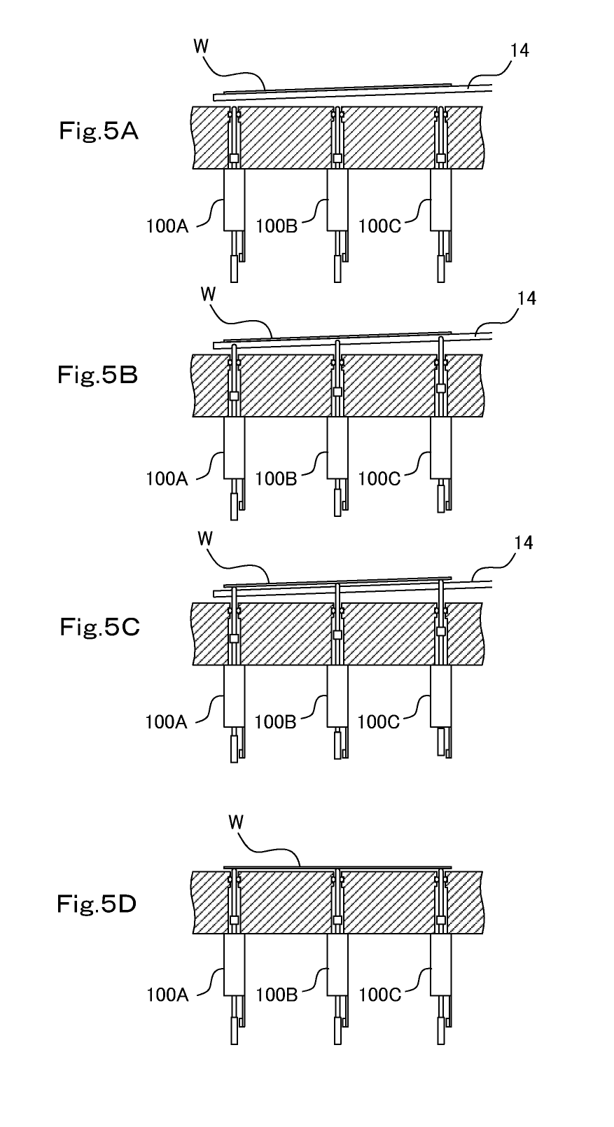

FIGS. 5A to 5D show a processing-object (wafer)-supporting method according to a third embodiment of the present invention, specifically, an operational flow of how the wafer W conveyed by the conveying arm 14 is transferred onto the lift pins 38A to 38C. For easier understanding, the lift pins 38A to 38C, which are actually provided along the circumference of a specific circle, are schematically shown side by side, and the conveying arm 14 is shown behind the lift pins 38A to 38C. FIG. 5A shows a state where the conveying arm 14 carrying the wafer W has entered the airtight chamber. Because of a bend in the conveying arm 14, the wafer W is tilted with respect to the reference surface. Prior to the conveyance by the conveying arm 14, the angles of tilt of the wafer W at positions corresponding to the three lift pins 38A to 38C, for example, the distances from the tips of the lift pins 38A to 38C to the undersurface of the wafer W, are measured individually so as to be utilized in generating position command values. In the third embodiment, the lift pins 38A to 38C are subsequently lifted at a high speed. FIG. 5B shows a state during such lifting, where the lift pins 38A to 38C are positioned close to but at some distances from the wafer W. That is, the lift pins 38A to 38C are moved in such a manner as to correspond to the tilt of the wafer W, whereby the distances from the lift pins 38A to 38C to the wafer W are made to be equal. In this state, the lift pins 38A to 38C are stopped temporarily or continue to be lifted at a low speed. FIG. 5C shows a state where the lift pins 38A to 38C that have come into contact with the wafer W are further lifted to such levels that the wafer W is lifted off the conveying arm 14. In this operation, the three lift pins 38A to 38C that have been moved at a low speed simultaneously come into contact with the wafer W. Therefore, compared with a case where the distances between the lift pins and the wafer are different, the wafer W is prevented from rippling on the lift pins 38A to 38C, and substantially no displacement of the wafer W occurs. After the lift pins 38A to 38C have come into contact with the wafer W, the lift pins 38A to 38C continue to be lifted at a low speed. In the third embodiment, after the entirety of the wafer W is supported by the lift pins 38A to 38C, the conveying arm 14 is moved away from the supporting mechanism. Subsequently, the lift pins 38A to 38C are moved such that the tips thereof are at the same level, that is, the wafer W becomes parallel to the reference surface (for example, the top surface of the bottom 44). Thus, as shown in FIG. 5D, the wafer W is positioned ready to be processed. For example, the wafer W is placed still on the top surface of the bottom 44.

By such a supporting method, the wafer placed on the conveying arm is transferred onto the lift pins with no considerable impact even if the wafer is tilted because of any bend in the conveying arm. Consequently, the displacement of the wafer that tends to occur in the known techniques when the wafer is transferred from the conveying arm is greatly reduced.

### Fourth Embodiment

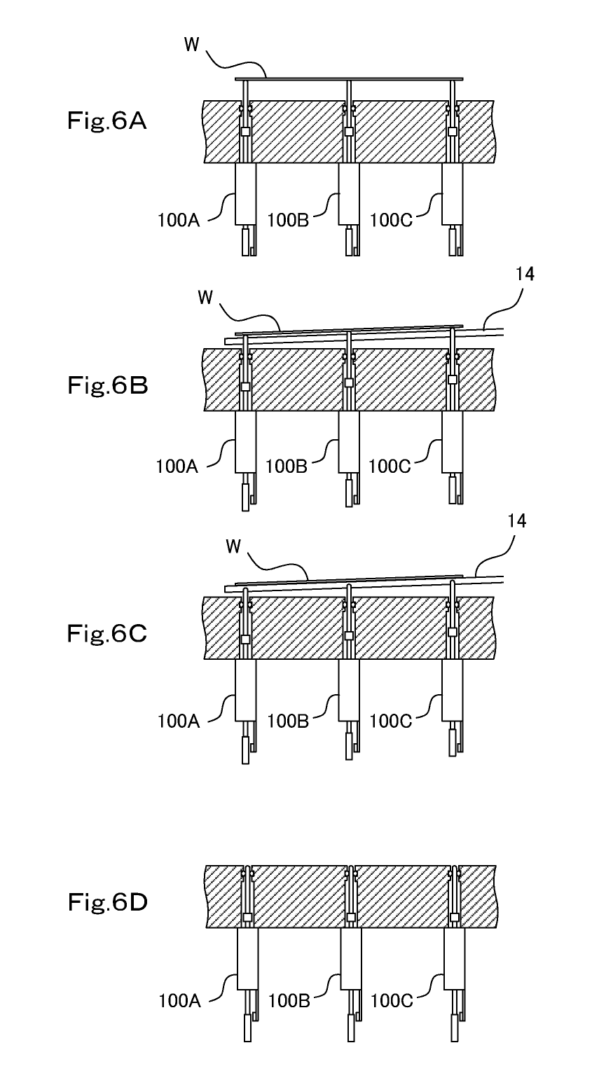

FIGS. 6A to 6D show a processing-object (wafer)-supporting method according to a fourth embodiment of the present invention, specifically, an operational flow of how the wafer W placed on the lift pins 38A to 38C is transferred onto the conveying arm 14. FIG. 6A shows a state where the wafer W is supported by the lift pins 38A to 38C. Considering the conveying arm 14 coming into the airtight chamber afterward, the wafer W is lifted higher than a level at which the conveying arm 14 is expected to approach. FIG. 6B shows a state where the conveying arm 14 has reached the supporting mechanism and the wafer W has been brought near to the conveying arm 14. Here, the angles of tilt of the wafer-receiving surface of the conveying arm 14 at positions corresponding to the three lift pins 38A to 38C, for example, the distances from the tips of the lift pins 38A to 38C to the wafer-receiving surface of the conveying arm 14, are measured in advance so as to be utilized in generating position command values. As shown in FIG. 6B, the lift pins 38A to 38C are independently driven such that the distances between the conveying arm 14 and the wafer W at the abovementioned positions all become equal, that is, the wafer-receiving surface of the conveying arm 14 becomes parallel to the wafer W. In this state, the lift pins 38A to 38C are stopped temporarily or continue to be lowered at a low speed. FIG. 6C shows a state where the wafer W has come into contact with the conveying arm 14 and the lift pins 38A to 38C has been further lowered. In this operation, the wafer W comes into contact with the conveying arm 14 with no considerable impact. After the entirety of the wafer W is supported by the conveying arm 14, the conveying arm 14 carrying the wafer W is moved away from the supporting mechanism. Subsequently, as shown in FIG. 6D, the lift pins 38A to 38C are moved to standby positions (herein, the positions shown in FIG. 6D) at a high speed and are stopped.

By such a supporting method, the wafer placed on the lift pins is transferred onto the conveying arm with no considerable impact even if the conveying arm is tilted with any bend. Consequently, the displacement of the wafer that tends to occur in the known techniques when the wafer is transferred to the conveying arm is greatly reduced.

### Fifth Embodiment

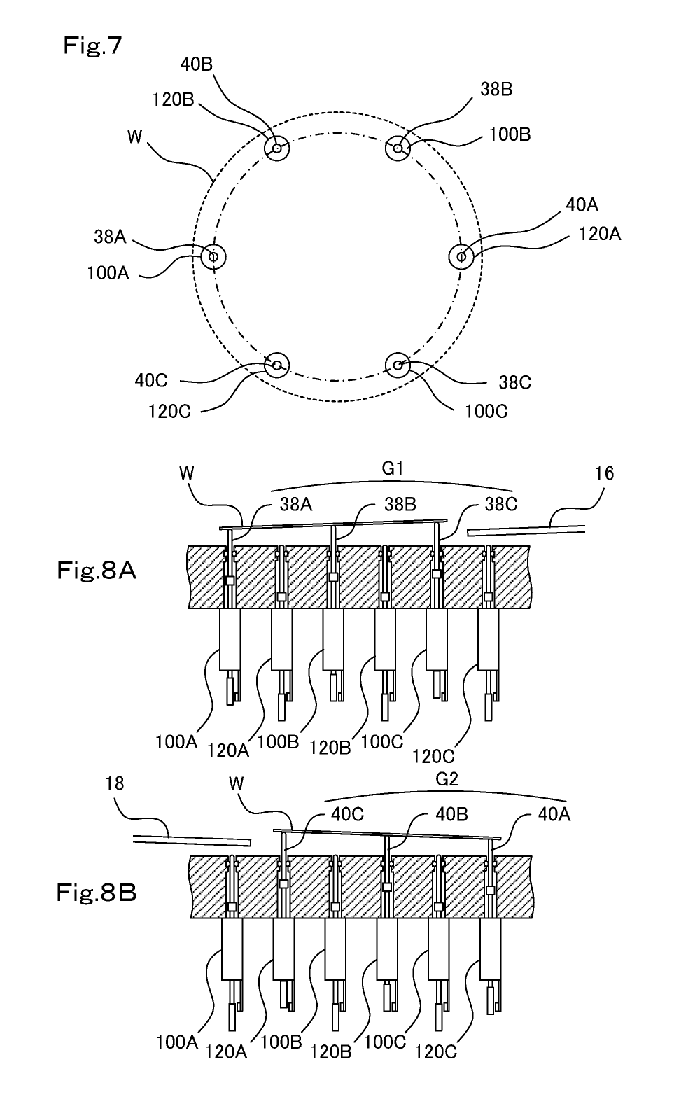

FIG. 7 shows the arrangement of lift pins and linear motors according to a fifth embodiment of the present invention. FIGS. 8A and 8B show a processing-object (wafer)-supporting method according to the fifth embodiment. Elements shown in FIGS. 7 to 8B include lift pins 40A to 40C, linear motors 120A to 120C, and conveying arms 16 and 18. A first group G1 includes at least three units each including one lift pin, one linear motor, and so forth. A second group G2 also includes at least three units each including one lift pin, one linear motor, and so forth. In FIGS. 8A and 8B, the lift pins 38A to 38C and the lift pins 40A to 40C, which are actually provided along the circumference of a specific circle, are schematically shown side by side for easier understanding.

In the fifth embodiment, the supporting mechanism includes two groups of three units, each unit being a combination of one lift pin; one linear motor; one position detector; and one drive control device. That is, the supporting mechanism according to the fifth embodiment includes a total of six units.

The first group G1 includes three units with the three respective lift pins 38A to 38C. The second group G2 includes three units with the three respective lift pins 40A to 40C. The lift pins 38A to 38C of the first group G1 and the lift pins 40A to 40C of the second group G2 are all arranged at constant intervals along the circumference of a specific circle that is to be concentric with the wafer W. FIG. 8A shows a state where the wafer W that has been conveyed from the right side by the conveying arm 16 is supported by the first group G1. FIG. 8B shows a state where the wafer W that has been conveyed from the left side by the conveying arm 18 is supported by the second group G2. The second group G2, in which the lift pin 40A is to be positioned below the conveying arm 16, cannot support the wafer W that is conveyed from the right side in FIGS. 8A and 8B. Meanwhile, the first group G1, in which the lift pin 38A is to be positioned below the conveying arm 18, cannot support the wafer W that is conveyed from the left side. Therefore, the first group G1 supports the wafer W conveyed from the right side by the conveying arm 16, and the second group G2 supports the wafer W conveyed from the left side by the conveying arm 18.

With such a supporting mechanism employing the above supporting method, the plurality of groups are selectively used such that the conveying arm and the lift pins do not interfere with each other even if the conveying arm enters the airtight chamber and supports the processing object in whichever direction, or even if the shape of the conveying arm has been changed. That is, the supporting mechanism supports a processing object that is conveyed in any direction. Moreover, the supporting mechanism supports the processing object with substantially no displacement even if the processing object is tilted at any angle because of any bend in the conveying arm.

### Sixth Embodiment

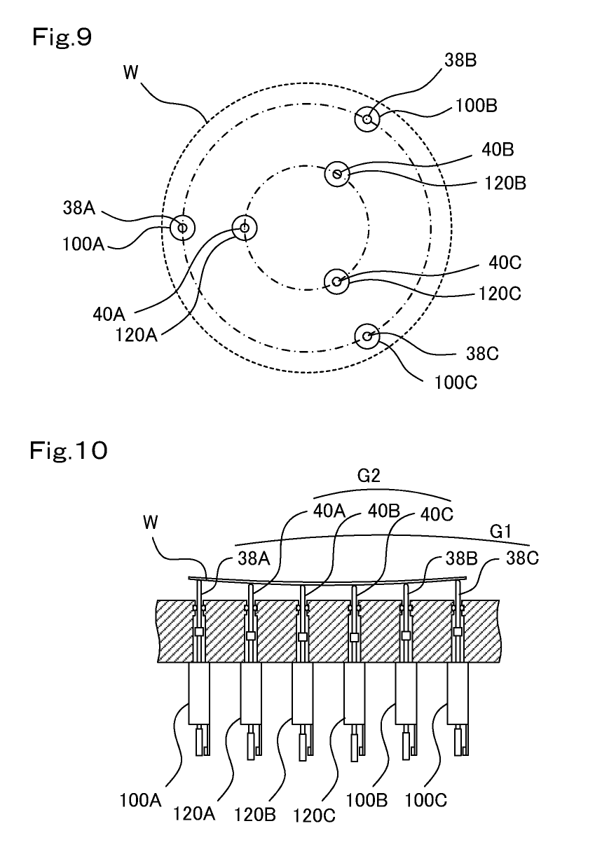

FIG. 9 shows the arrangement of lift pins and linear motors according to a sixth embodiment of the present invention. FIG. 10 shows a processing-object (wafer)-supporting method according to the sixth embodiment. In FIG. 10, the lift pins 38A to 38C and the lift pins 40A to 40C, which are actually provided along the circumferences of specific circles, are schematically shown side by side for easier understanding.

In the sixth embodiment, the first group G1 and the second group G2 are provided along the circumferences of concentric circles, respectively, having different diameters. The first group G1 is provided on the outer side and includes three units with the three respective lift pins 38A to 38C. The second group G2 is provided on the inner side and includes three units with the three respective lift pins 40A to 40C.

In such a supporting mechanism, stable support is provided by individually controlling the positions of the lift pins of the first and second groups G1 and G2 to correspond to any bend in the wafer W itself. A processing object having a large diameter (such as a wafer having a diameter of 450 mm) may be deformed into a complicated shape. According to the sixth embodiment, such a large wafer is also supported at a plurality of points in accordance with the complicated shape. Thus, any displacement of the processing object that may occur when the wafer is transferred from and to the conveying arm is suppressed.

Furthermore, in a case where the wafer is conveyed together with a conveyance ring also placed on the conveying arm so as to support the wafer by encircling the wafer, the first group G1 on the outer side may be used as the support for the conveyance ring, and the second group G2 on the inner side may be used as the support for the wafer.

Furthermore, in a case where wafers, as processing objects, having different diameters are conveyed in turns, the first and second groups G1 and G2 may be selectively used in accordance with the diameters.

While the processing object in each of the first to sixth embodiments is a wafer, if the above support mechanisms and methods are practiced with an increased number of units, the benefits described above are also provided in a mechanism and method of supporting a liquid-crystal-display (LCD) substrate or a glass substrate. Furthermore, the first and second groups may be selectively used before and after the processing of the processing object, before and after the heating or cooling process, or the like. While the linear motors in the above embodiments each have a cylindrical shape, general linear motors each including a flat slider and a flat stator may alternatively be employed. Needless to say, the benefits of the above embodiments of the present invention are provided as long as the lift pins and the position detectors are connected to the movable shafts of the linear motors in such a manner as to move together therewith. The movable shafts themselves may form sliders, or may be coupled to the sliders with other members interposed therebetween. Furthermore, the permanent magnets, as the field magnets, of the linear motors may alternatively be provided inside the movable shafts.

To summarize, according to an embodiment of the present invention, even if the processing object is tilted because of any bend in the conveying arm, or even if the processing object itself is deformed, the positions of the lift pins are individually and accurately controlled in accordance with the tilt and the deformation. Furthermore, even if there are any changes in the force of friction and/or the load, the positions of the lift pins are always accurately detected and are constantly controlled. That is, the displacement of the processing object that tends to occur in the known techniques when the processing object is transferred from and to the conveying arm is greatly reduced.

Furthermore, according to an embodiment of the present invention, the supporting mechanism includes at least three units each including one lift pin configured to support the processing object; one linear motor configured to lift and lower the lift pin; one position detector configured to detect the position of the lift pin in the direction of the movement thereof; and one drive control device. Therefore, the positions of a plurality of lift pins are controlled individually.

Furthermore, according to an embodiment of the present invention, the lift pins are fixed to the upper end of the movable shafts of the linear motors, and the position detectors are fixed to the lower end of the movable shafts, whereby the positions of the lift pins are directly and accurately detected. Therefore, even if the processing object is tilted because of any bend in the conveying arm, the positions of the lift pins are individually and accurately controlled to correspond to the tilt. Furthermore, even if there are any changes in the force of friction and/or the load, the positions of the lift pins are always accurately detected and are constantly controlled. That is, the displacement of the processing object that tends to occur in the known techniques when the processing object is transferred from and to the conveying arm is greatly reduced.

Furthermore, according to an embodiment of the present invention, the lift pin, the linear motor, and the position detector included in each of the units are arranged coaxially, so that long and narrow units of the supporting mechanism are provided. Such long and narrow units are arranged dispersively. Thus, large spaces are provided among the units. Since such large spaces are provided for the drive control devices and other electric components, the overall size of the processing apparatus can be reduced.

Furthermore, according to an embodiment of the present invention, the lift pin and the linear motor included in each of the units are arranged coaxially, and the position detector of each unit is provided parallel to the corresponding one of the linear motors, so that the heights of the units of the supporting mechanism are reduced. Such units having reduced heights are arranged dispersively. Since large spaces are provided among the units while the height of the supporting mechanism is suppressed, the overall size of the processing apparatus can be reduced.

Furthermore, according to an embodiment of the present invention, the lift pins are arranged at constant intervals along the circumference of a specific circle and the positions thereof are controlled individually. Therefore, even if the processing object is tilted because of any bend in the conveying arm, the processing object is supported stably. Consequently, the displacement of the processing object that tends to occur when the processing object is transferred from and to the conveying arm is reduced.

Furthermore, according to an embodiment of the present invention, the lift pins are arranged along the circumferences of different circles that are concentric with each other, and the positions of the lift pins are controlled individually. Therefore, even a processing object having a large diameter (for example, a wafer having a diameter of 450 mm) having a bend is supported stably. Consequently, the displacement of the processing object that tends to occur when the processing object is transferred from and to the conveying arm is reduced. In addition, in a case where the processing object is conveyed by the conveying arm together with a conveyance ring also placed on the conveying arm, the group of units on the outer side may be used as the support for the conveyance ring, and the group of units on the inner side may be used as the support for the processing object.

Furthermore, according to an embodiment of the present invention, the support mechanism includes a plurality of groups each including N units. Therefore, in whichever direction the conveying arm enters the airtight chamber and supports the processing object, the plurality of groups of units are selectively used so that the conveying arm and the lift pins do not interfere with each other. That is, the supporting mechanism supports a processing object that is conveyed in any direction. Moreover, the supporting mechanism supports the processing object with substantially no displacement even if the processing object is tilted at any angle because of any bend in the conveying arm.

Furthermore, according to an embodiment of the present invention, when a processing object placed on the conveying arm is transferred onto the N lift pins, or when a processing object supported by the N lift pins is transferred onto the conveying arm, the N lift pins are moved such that the distances from the N lift pins to the processing object or the distances from the processing object to the conveying arm at positions corresponding to the N lift pins all become equal, and are subsequently moved at a low speed. Therefore, the processing object is transferred with no considerable impact. Consequently, the displacement of the processing object that tends to occur when the processing object is transferred from and to the conveying arm is greatly reduced.

The processing-object-supporting mechanisms and methods according to the embodiments of the present invention realize improved accuracy and repeatability in the position of the processing object, compared with the known mechanisms and methods, and are therefore also applicable to a wafer stage included in a semiconductor exposure apparatus, for example. If the number of units each including one lift pin; one linear motor; one position detector; and one drive control device is increased, the above supporting mechanisms and methods are also applicable to apparatuses that process larger processing objects, such as an LCD substrate.

Obviously, numerous modifications and variations of the present invention are possible in light of the above teachings. It is therefore to be understood that within the scope of the appended claims, the invention may be practiced otherwise than as specifically described herein.

What is claimed as new and is desired to be secured by Letters Patent of the United States is:

1. A processing-object-supporting mechanism comprising:
at least three devices each comprising:
a lift pin to contact a processing object to support the processing object, the processing object being transferred between a conveying arm and the processing-object-supporting mechanism;
a motor to lift and lower the lift pin; and
a drive controller configured to control the motor, the drive controller of each of the at least three devices being configured to control the motor of each of the at least three devices independently.

2. The processing-object-supporting mechanism according to claim 1, further comprising:
a command device configured to give position command to the drive controller of each of the at least three devices,
wherein the processing object is transferred after the command device gives the position command to the drive controller of each of the at least three devices such that distance from a tip of the lift pin of each of the at least three devices to the processing object placed on the conveying arm or to a processing-object-receiving surface of the conveying arm all become equal, and after the drive controller of each of the at least three devices independently control the motor of each of the at least three devices.

3. The processing-object-supporting mechanism according to claim 1,
wherein the motor of each of the at least three devices is a linear motor.

4. The processing-object-supporting mechanism according to claim 3,
wherein the linear motor includes
a movable shaft at an upper end portion of which the lift pin is provided,
a field magnet provided around the movable shaft,
a frame holding an armature, the armature being provided around the field magnet with a gap interposed therebetween, and
a position detector provided at a lower end portion of the movable shaft, the movable shaft extending through a bottom of the frame.

5. The processing-object-supporting mechanism according to claim 1, comprising:
a plurality of groups each including the at least three devices,
wherein the at least three devices of all of the plurality of groups are arranged at constant intervals along a circumference of one circle.

6. The processing-object-supporting mechanism according to claim 1, comprising:
a plurality of groups each including the at least three devices,
wherein the at least three devices of each of the plurality of groups are arranged at constant intervals along circumferences of concentric circles having different diameters defined for the plurality of groups.

7. A supporting method employed in a supporting mechanism, comprising:
transferring a processing object after drive controllers independently control motors respectively such that distances from tips of lift pins to the processing object placed on a conveying arm or to a processing-object-receiving surface of the conveying arm all become equal, the processing object being transferred between the conveying arm and the supporting mechanism, the supporting mechanism including at least three devices each having one lift pin of the lift pins to contact the processing object to support the processing object, one motor of the motors to lift and lower the lift pin, and one drive controller of the drive controllers configured to control the motor.

8. The supporting method according to claim 7,
wherein, when the processing object conveyed to the supporting mechanism by the conveying arm is supported by the lift pins, the lift pins are driven by the motors at a high speed before the distances from the tips of the lift pins to the processing object placed on the conveying arm all become equal, respectively, and the lift pins are subsequently stopped temporarily or continue to be lifted simultaneously at a speed lower than the high speed.

9. The supporting method according to claim 7,
wherein, when the processing object supported by the lift pins are transferred onto the conveying arm, the lift pins are driven by the motors such that the processing object on the lift pins becomes parallel to the processing-object-receiving surface of the conveying arm, respectively, and the lift pins are subsequently stopped temporarily or continue to be lowered simultaneously.

10. A conveying system comprising:
a conveying arm configured to convey a processing object; and
a supporting mechanism with which the processing object is transferred from and to the conveying arm, the supporting mechanism including at least three devices each having
a lift pin to contacting the processing object to support the processing object,
a motor to lift and lower the lift pin, and
a drive controller configured to control the motor,
the processing object being transferred after the drive controller of each of the at least three devices independently controls the motor of each of the at least three devices such that distance from a tip of the lift pin of each of the at least three devices to the processing object placed on the conveying arm or to a processing-object-receiving surface of the conveying arm all become equal.

11. A processing-object-supporting mechanism comprising:
at least three devices each comprising:
a lift pin to contact a processing object to support the processing object, the processing object being transferred between a conveying arm and the processing-object-supporting mechanism;
a motor to lift and lower the lift pin; and
a drive controller configured to control the motor, the motor of each of the at least three devices being arranged to lift and lower the lift pin of each of the at least three devices provided in and fixed to an airtight chamber in which pressure is reduced, the processing object being transferred after the drive controller of each of the at least three devices independently controls the motor of each of the at least three devices in accordance with the pressure inside the airtight chamber such that distance from a tip of the lift pin of each of the at least three devices to the processing object placed on the conveying arm or to a processing-object-receiving surface of the conveying arm all become equal.
